(19) United States
(12) Patent Application Publication
(10) Pub. No.: US 2025/0359455 A1
(43) Pub. Date: Nov. 20, 2025

(54) DISPLAY DEVICE

(71) Applicant: Samsung Display Co., LTD., Yongin-si (KR)

(72) Inventors: Keun Young PARK, Yongin-si (KR); Seung Jun YU, Yongin-si (KR)

(21) Appl. No.: 18/991,235

(22) Filed: Dec. 20, 2024

(30) Foreign Application Priority Data
May 20, 2024 (KR) 10-2024-0065272

(51) Int. Cl. H10K 59/38; H10K 59/80

(52) U.S. Cl. CPC H10K 59/38; H10K 59/878

(57) ABSTRACT

A display device includes: a first substrate; a transistor on the first substrate; a light emitting device layer electrically connected to the transistor; a plurality of color conversion layers above the light emitting device layer; and a bulkhead between the plurality of color conversion layers, wherein the bulkhead comprises a first layer, a second layer, and a third layer, the first layer comprises a light blocking material, and the second layer comprises at least one of a metal or a metal oxide.

### CROSS-REFERENCE TO RELATED APPLICATION

The present application claims priority to and the benefit of Korean Patent Application No. 10-2024-0065272, filed on May 20, 2024, in the Korean Intellectual Property Office, the entire disclosure of which is incorporated herein by reference.

BACKGROUND

### 1. Field

Aspects of some embodiments of the present disclosure relate to a display device.

### 2. Description of the Related Art

A light emitting device is a device in which holes supplied from an anode and electrons supplied from a cathode combine to form exciton in a light emitting layer formed between the anode and the cathode, and the exciton is stabilized to emit light.

The light emitting device may be utilized in various electrical and electronic devices such as televisions, monitors, mobile phones, etc. owing to various advantages such as a relatively wide viewing angle, a relatively fast response speed, a relatively small thickness, a relatively low power consumption, etc.

The above information disclosed in this Background section is only for enhancement of understanding of the background and therefore the information discussed in this Background section does not necessarily constitute prior art.

### SUMMARY

In order to implement a high efficiency display device, a display device including a color conversion layer may be utilized. The color conversion layer may convert color of incident light into another color.

Aspects of some embodiments of the present disclosure include a display device including a bulkhead that may be capable of relatively improving light efficiency.

A display device according to some embodiments includes a first substrate, a transistor on the first substrate, a light emitting device layer electrically connected to the transistor, a plurality of color conversion layers above the light emitting device layer, and a bulkhead between the plurality of color conversion layers, wherein the bulkhead includes a first layer, a second layer, and a third layer, the first layer includes a light blocking material, and the second layer includes at least one of a metal or a metal oxide.

According to some embodiments, a height of the second layer may be 0.4 times or more a maximum height of the color conversion layer.

According to some embodiments, the second layer may include a photosensitive resin composition in which particles including at least one of the metal or the metal oxide are dispersed, and at least one of the metal or the metal oxide of the second layer may include at least one of aluminum (Al), titanium dioxide (TiO₂), silver (Ag), gold (Au), platinum (Pt), aluminum oxide (Al₂O₃), or zinc oxide (ZnO).

According to some embodiments, the second layer may further include an anti-oxidation layer on both side surfaces of the second layer.

According to some embodiments, the third layer may include a liquid repellent material, and the liquid repellent material may include a copolymer including a perfluoropolyether (PFPE) derivative as a side chain or a branch.

According to some embodiments, the display device may further include a filling layer between the color conversion layer and the bulkhead.

According to some embodiments, the display device may further include a color filter layer on the filling layer.

According to some embodiments, the display device may further include a second substrate on the color filter layer.

According to some embodiments, the display device may further include an insulating layer between the color conversion layer and the bulkhead.

According to some embodiments, the display device may further include a planarization layer on the insulating layer.

According to some embodiments, the second layer may be stacked on the first layer of the bulkhead, and the third layer may be stacked on the second layer.

According to some embodiments, the second layer may overlap an upper surface of the first layer and may be spaced apart from side surfaces of the first layer.

According to some embodiments, a maximum height of the color conversion layer may be Hᵢ, and an entire height of the bulkhead is H_{b}, H_{b} may be greater than Hᵢ and may satisfy H_{b}−Hᵢ≥0.5 μm.

According to some embodiments, the maximum height of the color conversion layer may be Hᵢ, and a height of the first layer is H₁, H₁≤0.3 Hᵢ may be satisfied.

According to some embodiments, the maximum height of the color conversion layer is Hᵢ, and a height of the third layer is H₃, H₃≤0.3 Hᵢ, and a maximum width of the third layer may be 6 μm or less on a cross section.

According to some embodiments, the first layer may overlap the second layer, and the second layer may cover side surfaces of the first layer.

According to some embodiments, the maximum height of the color conversion layer is Hᵢ, and a height of the second layer is H₂, H₂>0.6 Hᵢ may be satisfied.

A display device according to some embodiments includes a first substrate, a transistor on the first substrate, a light emitting device layer electrically connected to the transistor, a plurality of color conversion layers above the light emitting device layer, and a bulkhead between the plurality of color conversion layers, wherein the bulkhead includes a first layer, a second layer, and a third layer, the first layer includes a first material having a first reflectance, the second layer includes a second material having a second reflectance, and the first reflectance is lower than the second reflectance.

According to some embodiments, the first material having the first reflectance of the first layer includes MTO(MgTiO₃).

According to some embodiments, the second layer may include a photosensitive resin composition in which particles including the second material are dispersed, and the second material may include at least one of aluminum (Al), titanium dioxide (TiO₂), silver (Ag), gold (Au), platinum (Pt), aluminum oxide (Al₂O₃), or zinc oxide (ZnO).

According to some embodiments, an electronic device may comprise a display device. The display device may comprise a first substrate, a transistor on the first substrate, a light emitting device layer electrically connected to the transistor, a plurality of color conversion layers above the light emitting device layer, and a bulkhead between the plurality of color conversion layers. The bulkhead may comprise a first layer, a second layer, and a third layer. The first layer may comprise a light blocking material and the second layer may comprise at least one of a metal or a metal oxide.

According to some embodiments, the structure of the bulkhead of the present disclosure may relatively increase an aperture ratio and relatively increase a luminous efficiency, thereby maximizing or improving the efficiency of a high resolution display device.

### BRIEF DESCRIPTION OF THE DRAWINGS

FIG. 1 is a schematic exploded perspective view of a display device according to some embodiments.

FIG. 2 is a schematic cross-sectional view of a display panel according to some embodiments.

FIG. 3 is a cross-sectional view of a display panel according to some embodiments.

FIG. 4 is an enlarged cross-sectional view of a partial area of a display panel according to some embodiments.

FIG. 5 is a cross-sectional view of a display panel according to some embodiments.

FIGS. 6 and 7 are enlarged cross-sectional views of a partial area of a display panel according to some embodiments.

FIG. 8 is a graph showing light emission efficiency of white light of a display panel according to some embodiments and comparative examples.

FIG. 9 is a block diagram of an electronic device according to some embodiments.

FIGS. 10 to 12 are schematic diagrams of electronic devices according to some embodiments.

### DETAILED DESCRIPTION

With reference to the attached drawings, aspects of some embodiments of the present disclosure will be described in more detail below so that ordinary skilled in the art may easily implement the disclosure. The present disclosure may be embodied in many different forms and is not limited to the embodiments set forth herein.

In order to clearly explain the present disclosure in the drawings, parts irrelevant to the description are omitted, and the same reference numerals are used for the same or similar elements throughout the specification.

In addition, because the size and thickness of each component shown in the drawings are arbitrarily shown for convenience of description, the present disclosure is not necessarily limited to those shown. In the drawings, the thickness of layers and regions are exaggerated for clarity. In addition, in the drawings, for convenience of explanation, thicknesses of some layers and areas are exaggerated.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

In addition, throughout the specification, unless explicitly described to the contrary, the word “comprise”, and variations such as “comprises” or “comprising”, will be understood to imply the inclusion of stated elements but not the exclusion of any other elements.

In addition, throughout the specification, when it is “on a plane” means when a target portion is viewed from above, and when it is “on a cross section” means when a cross section obtained by vertically cutting a target portion is viewed from the side.

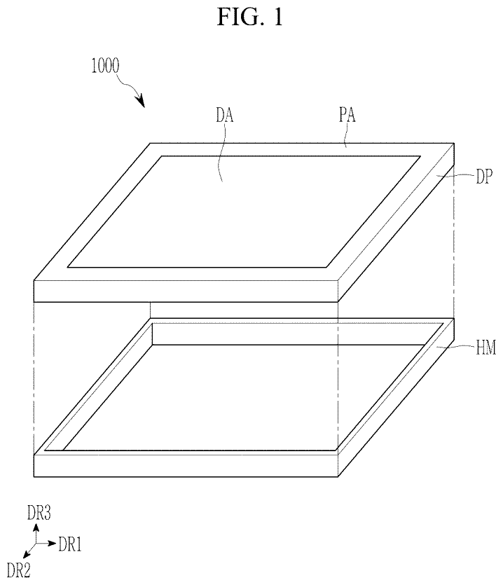

Hereinafter, a display device according to some embodiments will be described in more detail with reference to FIG. 1. FIG. 1 is a schematic exploded perspective view of a display device according to some embodiments.

Referring to FIG. 1, a display device 1000 according to some embodiments may include a display panel DP and a housing HM.

One surface of the display panel DP on which images are displayed is parallel to a surface defined by a first direction DR1 and a second direction DR2. A normal direction of one surface on which the images are displayed, that is, a thickness direction of the display panel DP, is indicated by a third direction DR3. A front surface (or an upper surface) and a rear surface (or a lower surface) of each of members are divided by the third direction DR3. However, the directions indicated by the first to third directions DR1, DR2, and DR3 may be converted into other directions as a relative concept.

The display panel DP may be a flat rigid display panel, but is not limited thereto and may be a flexible display panel. Meanwhile, the display panel DP may be configured as an organic light emitting display panel. However, a type of the display panel DP is not limited thereto, and may be configured as various types of panels. For example, the display panel DP may be configured as a liquid crystal display panel, an electrophoretic display panel, or an electrowetting display panel. In addition, the display panel DP may be configured as a next generation display panel such as a micro light emitting diode (LED) display panel, a quantum dot LED display panel, or a quantum dot organic LED display panel.

The micro LED display panel includes LEDs with a size of 10 micrometers to 100 micrometers forming each pixel. The micro LED display panel has advantages of using an inorganic material, being able to omit a backlight, having a fast response speed, being able to achieve high brightness with low power, not breaking when bent, etc.

The quantum dot LED display panel is configured by attaching a film including quantum dots or being forming of a material including quantum dots. A quantum dot refers to a particle that is made of an inorganic material such as indium, cadmium, etc., self-emits light, and has a diameter of several nanometers or less. The quantum dot LED display panel may display light of a desired color by adjusting the particle size of the quantum dot. The quantum dot LED display panel is configured by using a blue organic LED as a light source, attaching a film including red and green quantum dots thereon, or depositing a material including red and green quantum dots to realize a color. The display panel DP according to some embodiments may be configured as a variety of other display panels.

As shown in FIG. 1, the display panel DP includes a display area DA at which images are displayed, and a non-display area PA adjacent to the display area DA. The non-display area PA is an area at which no images are displayed. According to some embodiments, the non-display area PA may be an area surrounding (e.g., in a periphery or outside a footprint of) the display area DA. The display area DA may have, for example, a rectangular shape, and the non-display area PA may have a shape surrounding the display area DA. However, the present disclosure is not limited thereto, and shapes of the display area DA and the non-display area PA may be relatively designed.

The housing HM provides a certain inside space. The display panel DP is mounted inside the housing HM. In addition to the display panel DP, various electronic parts, for example, a power supply unit, a storage device, an audio input/output module, etc. may be mounted inside the housing HM.

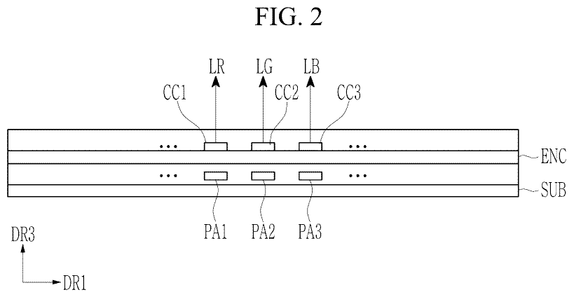

Hereinafter, a display area of a display panel according to some embodiments will be described with reference to FIG. 2. FIG. 2 is a schematic cross-sectional view of the display panel according to some embodiments.

Referring to FIG. 2, a plurality of pixels PA1, PA2, and PA3 may be formed on a substrate SUB corresponding to the display area DA of FIG. 1. Each of the pixels PA1, PA2, and PA3 may include a plurality of transistors and a light emitting device connected thereto.

The present specification describes aspects of some embodiments in which the plurality of pixels PA1, PA2, and PA3 are repeatedly arranged in a stripe shape or configuration or pattern, but embodiments according to the present disclosure are not limited thereto, and the shape and arrangement of each pixel may be modified in various ways.

An encapsulation layer ENC may be located on the plurality of pixels PA1, PA2, and PA3. The display area DA may be protected from external air or moisture through the encapsulation layer ENC. The encapsulation layer ENC may be integrally provided to overlap a front surface of the display area DA, and may be partially located on the non-display area PA.

A first color conversion unit CC1, a second color conversion unit CC2, and a transmission unit CC3 may be located on the encapsulation layer ENC. The first color conversion unit CC1 may overlap a first pixel PA1, the second color conversion unit CC2 may overlap a second pixel PA2, and the transmission unit CC3 may overlap a third pixel PA3.

Light emitted from the first pixel PA1 may pass through the first color conversion unit CC1 to provide a red light LR. Light emitted from the second pixel PA2 may pass through the second color conversion unit CC2 to provide a green light LG. Light emitted from the third pixel PA3 may pass through the transmission unit CC3 to provide a blue light LB.

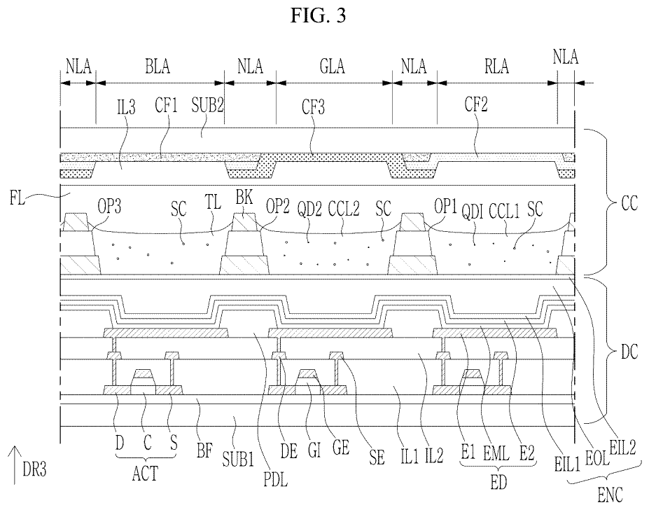

Hereinafter, a display panel according to some embodiments will be described in more detail with reference to FIG. 3. FIG. 3 is a cross-sectional view of the display panel according to some embodiments.

A display unit DC according to some embodiments includes a first substrate SUB1. The first substrate SUB1 may include a glass material or a flexible material such as plastic that may be well curved, bent, folded, or rolled.

A buffer layer BF may be located on the first substrate SUB1. According to some embodiments, the buffer layer BF may be omitted. The buffer layer BF may include silicon nitride (SiNₓ), silicon oxide (SiO₂), silicon oxynitride, etc. The buffer layer BF may be located between the first substrate SUB1 and a semiconductor layer ACT, block impurities from the first substrate SUB1 during a crystallization process for forming polycrystalline silicon to relatively improve characteristics of polycrystalline silicon, and planarize the first substrate SUB1 to relieve stress of the semiconductor layer ACT formed on the buffer layer BF.

The semiconductor layer ACT is located on the buffer layer BF. The semiconductor layer ACT may be formed of polycrystalline silicon or an oxide semiconductor. The semiconductor layer ACT includes a channel region C, a source region S, and a drain region D. The source region S and the drain region D are respectively arranged at both sides of the channel region C. The channel region C is an intrinsic semiconductor undoped with impurities, and the source region S and the drain region D are impurity semiconductors doped with conductive impurities. The semiconductor layer ACT may be formed of an oxide semiconductor, and in this case, a separate protective layer may be added to protect an oxide semiconductor material vulnerable to an external environment such as a high temperature, etc.

A gate insulating layer GI is located on the semiconductor layer ACT. The gate insulating layer GI may be a single layer or multiple layers including at least one of silicon nitride (SiNₓ), silicon oxide (SiO₂), or silicon oxynitride.

A gate electrode GE is located on the gate insulating layer GI. The gate electrode GE may be a multilayer in which metal layers each including any one of copper (Cu), a copper alloy, aluminum (Al), an aluminum alloy, molybdenum (Mo), and a molybdenum alloy are stacked.

An interlayer insulating layer IL1 is located on the gate electrode GE and the gate insulating layer GI. The interlayer insulating layer IL1 may include silicon nitride (SiNₓ), silicon oxide (SiO₂), silicon oxynitride, etc. An opening exposing each of the source region S and the drain region D is positioned in the interlayer insulating layer IL1.

The source electrode SE and the drain electrode DE are located on the interlayer insulating layer IL1. The source electrode SE and the drain electrode DE are respectively connected to the source region S and the drain region D of the semiconductor layer ACT through the openings formed in the interlayer insulating layer IL1.

A protective layer IL2 is located on the interlayer insulating layer IL1, the source electrode SE, and the drain electrode DE. The protective layer IL2 may cover and planarize the interlayer insulating layer IL1, the source electrode SE, and the drain electrode DE, so that a first electrode E1 may be formed on the protective layer IL2 without a step difference. The protective layer IL2 may be formed of an organic material such as a polyacrylates resin and a polyimides resin, or a stack film of an organic material and an inorganic material, etc.

The first electrode E1 is located on the protective layer IL2. The first electrode E1 is connected to the drain electrode DE through an opening of the protective layer IL2.

A driving transistor including the gate electrode GE, the semiconductor layer ACT, the source electrode SE, and the drain electrode DE is connected to the first electrode E1 to supply a driving current to a light emitting device ED. In addition to the driving transistor shown in FIG. 3, the display device according to some embodiments may further include a switching transistor connected to a data line and transmitting a data voltage in response to a scan signal, and a compensation transistor connected to the driving transistor and compensating for a threshold voltage of the driving transistor in response to the scan signal.

A pixel defining layer PDL may be located on the protective layer IL2 and the first electrode E1, and the pixel defining layer PDL may have a pixel opening overlapping the first electrode E1 and defining a light emitting region

The pixel defining layer PDL may include an organic material such as a polyacrylates resin and a polyimides resin, or a silica-based inorganic material. The pixel opening may have a planar shape almost similar to that of the first electrode E1, and may have a rhombus shape on a plane (e.g., in a plan view) or an octagonal shape similar to a rhombus, but is not limited thereto and may have any shape such as a square or a polygon.

An emission layer EML is located on the first electrode E1 overlapping the pixel opening. The emission layer EML may be formed of a low molecular organic material or a polymer organic material such as poly 3,4-ethylenedioxythiophene (PEDOT). In addition, the emission layer EML may be a multilayer further including one or more of a hole injection layer (HIL), a hole transporting layer (HTL), an electron transporting layer (ETL), and an electron injection layer (EIL).

The emission layer EML may be mostly located within the pixel opening, and may also be located on a side surface or on the pixel defining layer PDL. The present specification illustrates embodiments in which the emission layer EML continuously overlaps the front surface of the first substrate SUB1, but the embodiments according to the present disclosure are not limited thereto, and embodiments in which the emission layer EML is located only within the pixel opening of the pixel defining layer PDL is also possible.

A second electrode E2 is located on the emission layer EML. The second electrode E2 may be located over a plurality of pixels, and may receive a common voltage through a common voltage transfer unit in a non-display area.

The first electrode E1, the emission layer EML, and the second electrode E2 may constitute the light emitting device ED. Here, the first electrode E1 may be an anode which is a hole injection electrode, and the second electrode E2 may be a cathode which is an electron injection electrode. However, the embodiments according to the present disclosure are not limited thereto, and the first electrode E1 may be a cathode and the second electrode E2 may be an anode according to a driving method of an organic light emitting display device.

Holes and electrons are injected into the emission layer EML from the first electrode E1 and the second electrode E2, respectively, and light emission occurs when exciton in which the injected holes and electrons are combined falls from an excited state to a ground state.

Meanwhile, the light emitting device ED according to some embodiments may include a plurality of light emitting units. Each of the plurality of light emitting units may include a light emitting layer. That is, the light emitting device ED according to some embodiments may include a plurality of light emitting layers. The light emitting device ED may be a light emitting device in a tandem structure. The plurality of light emitting layers may emit the same light or different light. For example, the light emitting device ED may emit light in which green light and blue light are mixed, or may emit blue light.

The encapsulation layer ENC is located on the second electrode E2. The encapsulation layer ENC may cover not only an upper surface but also a side surface of a display layer including the light emitting device ED to seal the display layer.

Because the light emitting device ED is very vulnerable to moisture and oxygen, the encapsulation layer ENC seals the display layer to block inflow of external moisture and oxygen. The encapsulation layer ENC may include a plurality of layers, may be formed as a composite layer including both an inorganic layer and an organic layer among them, and may be formed as a triple layer in which a first inorganic layer EIL1, an organic layer EOL, and a second inorganic layer EIL2 are sequentially formed.

A color conversion unit CC is located on the encapsulation layer ENC. The color conversion unit CC includes a first color conversion layer CCL1, a second color conversion layer CCL2, a transmission layer TL, a bulkhead BK, a first color filter CF1, a second color filter CF2, a third color filter CF3, and a second substrate SUB2.

The bulkhead BK is located on the encapsulation layer ENC. The bulkhead BK may include a first opening OP1, a second opening OP2, and a third opening OP3 which overlap the pixel opening. The sizes of the first opening OP1, the second opening OP2, and the third opening OP3 may be different from or the same as each other.

The bulkhead BK may be located between the first color conversion layer CCL1 and the second color conversion layer CCL2 or between the second color conversion layer CCL and the transmission layer TL.

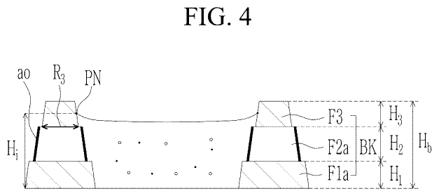

Hereinafter, a structure of a bulkhead will be described in detail with reference to FIG. 4. FIG. 4 is an enlarged cross-sectional view of the bulkhead which is a partial area of a display panel according to some embodiments.

The bulkhead BK according to some embodiments includes a first layer F1a, a second layer F2a, and a third layer F3.

The first layer F1a may include a light blocking material. The light blocking material may include a colored insulating material and may have black. In addition, the light blocking material may be an organic material including at least one material selected from the group consisting of polyimide, polyamide, acrylic resin, benzocyclobutene, and phenol resin. The light blocking material is not limited thereto, and may not be particularly limited as long as it may absorb light and shield light. The light blocking material may enable preventing or reducing color mixing between the first color conversion layer CCL1, the second color conversion layer CCL2, and the transmission layer TL through the first layer F1a.

The second layer F2a is stacked on the first layer F1a and located on the first layer F1a. The second layer F2a may include at least one of a metal or a metal oxide. In this case, the second layer F2a may be formed of a single material including at least one of the metal or the metal oxide, or may be formed of a material in which particles including the metal and the metal oxide are dispersed in a photosensitive resin composition. At least one of the metal or the metal oxide may include at least one of aluminum (Al), titanium dioxide (TiO₂), silver (Ag), gold (Au), platinum (Pt), aluminum oxide (Al₂O₃), or zinc oxide (ZnO). The second layer F2a may reflect light emitted toward side portions of the first color conversion layer CCL1 and the second color conversion layer CCL2 and emit the light toward the second substrate SUB2 or a planarization layer OC that is described below.

The third layer F3 is stacked on the second layer F2a and located on the second layer F2a. The third layer F3 includes a liquid repellent material. The liquid repellent material may include a copolymer including a perfluoropolyether (PFPE) derivative as a side chain or a branch. The liquid repellent material is not limited thereto, and may not be particularly limited if it has liquid repellency.

Because the third layer F3 has liquid repellency, spreadability of droplets miscarried on the bulkhead BK or at the edge of the bulkhead BK may be controlled during an inkjet process for forming the first color conversion layer CCL1, the second color conversion layer CCL2, and the transmission layer TL, thereby preventing or reducing the droplets staying on the bulkhead BK or at the edge of the bulkhead BK, and reducing sizes of the miscarried droplets. When droplets are miscarried on the bulkhead BK, the quality (e.g., adhesion, flatness, etc.) of a layer formed in a subsequent process may be deteriorated, and thus, it may be necessary to remove the droplets or reduce sizes of the droplets. The third layer F3 may form ink and a pinning point PN. In this case, the pinning point PN refers to a position at which droplets of ink applied in the bulkhead BK are fixed when a critical concentration is reached by drying.

In this case, an entire height H_{b} of the bulkhead BK is greater than a maximum height Hᵢ of a color conversion layer. A difference between the maximum height Hᵢ of the color conversion layer and the entire height H_{b} of the bulkhead BK is 0.5 μm or more. A height H₁ of the first layer F1a is 0.3 times or less the maximum height Hᵢ of the color conversion layer. Likewise, a height H₃ of the third layer F3 is 0.3 times or less the maximum height Hᵢ of the color conversion layer. A height H₂ of the second layer F2a is 0.4 times or more the maximum height Hᵢ of the color conversion layer.

In addition, in order to facilitate the ink process, a maximum width R₃ of a lower surface of the third layer F3 may be 6 μm or less on a cross section. The maximum width R₃ of the third layer F3 may be less than 3 μm as the height H₁ of the first layer F1a and the height H₃ of the third layer F3 decrease, which may exhibit the effect that the less the maximum width R₃, the higher the aperture ratio.

In this case, when the second layer F2a reacts with oxygen and is easily oxidized, there is a problem that durability deteriorates. To overcome this, an anti-oxidation layer ao may be coated on both side surfaces of the second layer F2a. The anti-oxidation layer ao may include a compound including titanium nitride (TiNₓ), titanium oxide (TiOₓ), and aluminum as elements. In addition, any material of the anti-oxidation layer ao may be used as long as it may prevent or reduce oxidation of metal of the second layer F2a.

Referring back to FIG. 3, the first color conversion layer CCL1 may be located within the first opening OP1. The first color conversion layer CCL1 May convert supplied light into red. The first color conversion layer CCL1 may include a first quantum dot QD1 and a scatterer SC.

The second color conversion layer CCL2 may be located within the second opening OP2. The second color conversion layer CCL2 may convert supplied light into green. The second color conversion layer CCL2 may include a second quantum dot QD2 and the scatterer SC.

The transmission layer TL may be located within the third opening OP3. The transmission layer TL may be located at a part in space partitioned by the bulkhead BK corresponding to a blue light emitting area BLA. The transmission layer TL may transmit light incident from the light emitting device ED. The transmission layer TL may include the scatterer SC. The scatterer SC may be at least one selected from the group consisting of SiO₂, BaSO₄, Al₂O₃, ZnO, ZrO₂, and TiO₂.

Hereinafter, quantum dots including the first quantum dot QD1 and the second quantum dot QD2 will be described in detail.

In the present specification, a quantum dot (hereinafter, referred to as a semiconductor nanocrystal) may include a Group II-VI compound, a Group III-V compound, a Group IV-VI compound, a Group IV element or compound, a Group I-III-VI compound, a Group I-II-IV-VI compound, or combinations thereof.

The Group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof, a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The Group II-VI compound may further include a Group III metal.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The Group III-V compound may further include Group II metal (e.g., InZnP).

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof.

The Group IV element or compound may be selected from the group consisting of a single element selected from the group consisting of Si, Ge, and a combination thereof; and a binary compound selected from the group consisting of SiC, SiGe, and a combination thereof, but is not limited thereto.

Examples of the Group I-III-VI compound include CuInSe₂, CuInS₂, CuInGaSe, and CuInGaS, but are not limited thereto. Examples of the Group I-II-IV-VI compound include CuZnSnSe, and CuZnSnS, but are not limited thereto. The Group IV element or compound may be selected from the group consisting of a single compound selected from the group consisting of Si, Ge and mixtures thereof; and a binary compound selected from the group consisting of SiC, SiGe and mixtures thereof.

The Group II-III-VI compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof, but is not limited thereto.

The Group I-II-IV-VI compound may be selected from CuZnSnSe and CuZnSnS, but is not limited thereto.

In an implementation example, the quantum dot may not include cadmium. The quantum dot may include a semiconductor nanocrystal based on the Group III-V compound including indium and phosphorus. The Group III-V compound may further include zinc. The quantum dot may include a semiconductor nanocrystal based on the Group II-VI compound including a chalcogen element (e.g., sulfur, selenium, tellurium, or a combination thereof) and zinc.

In the quantum dot, the binary, ternary and/or quaternary compounds described above may exist in particles at a uniform concentration, or may exist in the same particle with a partially different concentration distribution. In addition, one quantum dot may have a core/shell structure surrounding another quantum dot. An interface between a core and a shell may have a concentration gradient in which the concentration of an element present in the shell decreases toward the center.

According to some embodiments, the quantum dot may have the core-shell structure including the core including the nanocrystal described above and the shell surrounding the core. The shell of the quantum dot may serve as a protective layer for maintaining semiconductor properties by preventing or reducing chemical denaturation of the core and/or as a charging layer for imparting electrophoretic properties to the quantum dot. The shell may be a single layer or multiple layers. The interface between the core and the shell may have a concentration gradient in which the concentration of the element present in the shell decreases toward the center. Examples of the shell of the quantum dot may include an oxide of metal or non-metal, a semiconductor compound, or a combination thereof.

For example, examples of the oxide of metal or non-metal may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the present disclosure is not limited thereto.

The interface between the core and the shell may have a concentration gradient in which the concentration of the element present in the shell decreases toward the center. In addition, the semiconductor nanocrystal may have a structure including one semiconductor nanocrystal core and a multilayer shell surrounding the semiconductor nanocrystal core. In one implementation example, the multilayer shell may have two or more layers, for example, 2, 3, 4, 5, or more layer. Two adjacent layers of the shell may have a single composition or different compositions. Each of the layers in the multilayer shell may have a composition that varies along a radius.

The quantum dot may have a full width of half maximum (FWHM) of an emission wavelength spectrum of 45 nanometers (nm) (or about 45 nm) or less, preferably 40 nm (or about 40 nm) or less, and more preferably 30 nm (or about 30 nm) or less, and may relatively improve color purity or color reproducibility in these ranges. In addition, light emitted through the quantum dot is discharged in all directions, and thus, a light viewing angle may be relatively improved.

In the quantum dot, a shell material and a core material may have different energy band gaps. For example, the energy bandgap of the shell material may be larger than that of the core material. In another implementation example, the energy bandgap of the shell material may be smaller than that of the core material. The quantum dot may have a multilayer shell. An energy bandgap of an outer layer in the multilayer shell may be larger than an energy bandgap of an inner layer (i.e., a layer close to the core). The energy bandgap of the outer layer in the multilayer shell may be smaller than the energy bandgap of the inner layer.

The quantum dot may control an absorption/emission wavelength by adjusting its composition and size. The maximum emission peak wavelength of the quantum dot may have an ultraviolet or infrared wavelength range or greater wavelength range.

The quantum dot may have a quantum efficiency of 10% (or about 10%) or more, for example, 30% (or about 30%) or more, 50% (or about 50%) or more, 60% (or about 60%) or more, 70% (or about 70%) or more, 90% (or about 90%) or more, or even 100%. The quantum dot may have a relatively narrow spectrum. The quantum dot may have, for example, a FWHM of an emission wavelength spectrum in a range of 50 nm (or about 50 nm) or less, for example, 45 nm (or about 45 nm) or less, 40 nm (or about 40 nm) or less, or 30 nm (or about 30 nm) or less.

The quantum dot may have a particle size of 1 nm (or about 1 nm) or more and 100 nm (or about 100 nm) or less. The particle size refers to a diameter converted by assuming a sphere from a 2-dimensional (2D) image obtained by particle diameter or transmission electron microscope analysis. The quantum dot may have a size in a range of 1 nm (or about 1 nm) to 20 nm (or about 20 nm), for example, 2 nm or more, 3 nm or more, or 4 nm or more and 50 nm or less, 40 nm or less, 30 nm or less, 20 nm or less, 15 nm or less, for example, 10 nm or less. The shape of the quantum dot is not particularly limited. For example, the shape of the quantum dot may include a sphere, a polyhedron, a pyramid, a multipod, a square, a rectangular parallelepiped, a nanotube, a nanorod, a nanowire, a nanosheet, or a combination thereof, but is not limited thereto.

The quantum dot may be commercially available or appropriately synthesized. The quantum dot may adjust the particle size relatively freely and uniformly during colloid synthesis.

The quantum dot may include an organic ligand (e.g., having a hydrophobic residue and/or a hydrophilic residue). The organic ligand residue may be bonded to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein R may each independently be a C3 to C40 substituted or unsubstituted aliphatic hydrocarbon group such as a C3 to C40 (e.g., C5 or more and C24 or less) substituted or unsubstituted alkyl or substituted or unsubstituted alkenyl, a C6 to C40 (e.g., C6 or more and C20 or less) substituted or unsubstituted aromatic hydrocarbon group such as a C6 to C40 substituted or unsubstituted aryl group, etc., or a combination thereof.

Examples of the organic ligand may include a thiol compound such as methanethiol, ethanethiol, propanethiol, butanethiol, pentanethiol, hexanethiol, octanethiol, dodecanethiol, hexadecanethiol, octadecanethiol, benzyl thiol, etc.; amines such as methanamine, ethanoamine, propanoamine, butanoamine, pentylamine, hexylamine, octylamine, nonylamine, decylamine, dodecylamine, hexadecylamine, octadecylamine, dimethylamine, diethylamine, dipropylamine, tributylamine, trioctylamine, etc.; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, etc.; a phosphine compound such as methyl phosphine, ethyl phosphine, propyl phosphine, butyl phosphine, pentyl phosphine, octylphosphine, dioctyl phosphine, tributylphosphine, trioctylphosphine, etc.; a phosphine compound such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, trioctylphosphine oxide, etc. or an oxide compound thereof; diphenylphosphine, a triphenylphosphine compound or an oxide compound thereof; a C5 to C20 alkyl phosphinic acid and a C5 to C20 alkyl phosphonic acid, such as hexylphosphinic acid, octylphosphinic acid, dodecanephosphinic acid, tetradecanephosphinic acid, hexadecanephosphinic acid, octadecanephosphinic acid, etc., but are not limited thereto. The quantum dot may include a hydrophobic organic ligand alone or in a mixture of one or more hydrophobic organic ligands. The hydrophobic organic ligand (e.g., an acrylate group, a methacrylate group, etc.) may not include a photopolymerizable residue.

The color conversion unit CC includes the first color filter CF1, the second color filter CF2, and the third color filter CF3 located between the second substrate SUB2 and the display unit DC.

The second substrate SUB2 may overlap the first substrate SUB1 and include a glass material or a flexible material such as plastic that may be well curved, bent, folded, or rolled.

The first color filter CF1 may overlap the transmission layer TL. The first color filter CF1 may transmit blue light having passed through the transmission layer TL and absorb light of the remaining wavelength, thereby increasing a purity of the blue light emitted to the outside of the display device.

The second color filter CF2 may overlap the first color conversion layer CCL1. The second color filter CF2 may transmit red light having passed through the first color conversion layer CCL1 and absorb light of the remaining wavelength, thereby increasing a purity of the red light emitted to the outside of the display device.

The third color filter CF3 may overlap the second color conversion layer CCL2. The third color filter CF3 may transmit green light having passed through the second color conversion layer CCL2 and absorb light of the remaining wavelength, thereby increasing a purity of the green light emitted to the outside of the display device.

At least two of the third color filter CF3, the second color filter CF2, and the first color filter CF1 may overlap in a non-light emitting area NLA to serve as a light blocking member. The non-light emitting area NLA may overlap the pixel defining layer PDL of the display unit DC and the bulkhead BK of the color conversion unit CC.

A third insulating layer IL3 may be located between the color filters CF1, CF2, and CF3 and the display unit DC. For example, the third insulating layer IL3 may include, for example, an organic material or may include an inorganic material such as silicon nitride (SiNₓ), silicon oxide (SiO₂), silicon oxynitride, etc.

A filling layer FL may be located between the third insulating layer IL3 and the display unit DC. The filling layer FL may bond a component formed on the first substrate SUB1 and a component formed on the second substrate SUB2. The first substrate SUB1 and the second substrate SUB2 may be bonded to each other by the filling layer FL.

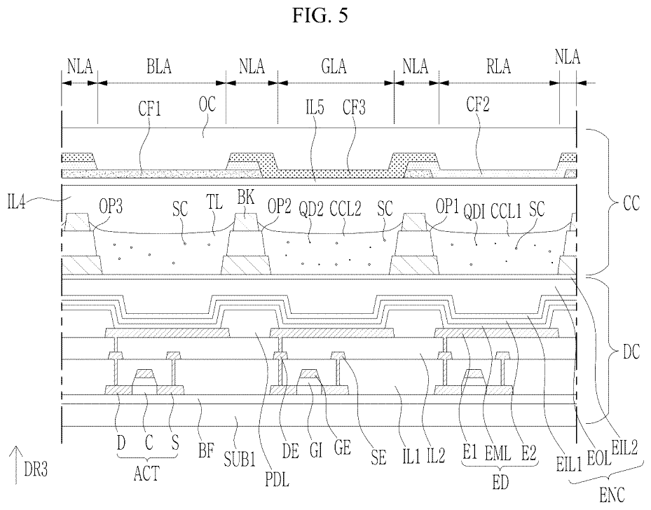

Hereinafter, modified embodiments of FIG. 3 will be described with reference to FIG. 5. FIG. 5 is a cross-sectional view of a display panel according to some embodiments.

The bulkhead BK, the first color conversion layer CCL1, the second color conversion layer CCL2, and the transmission layer TL may be located on the encapsulation layer ENC. A fourth insulating layer IL4 and a fifth insulating layer IL5 may be sequentially arranged on the bulkhead BK, the first color conversion layer CCL1, the second color conversion layer CCL2, and the transmission layer TL. The fourth insulating layer IL4 and the fifth insulating layer IL5 may each independently include an organic material or an inorganic material. For example, the fourth insulating layer IL4 may include an organic material, and the fifth insulating layer IL5 may include an inorganic material. According to some embodiments, a separate inorganic protective layer may be located in a lower portion of the fourth insulating layer IL4.

The first color filter CF1, the second color filter CF2, and the third color filter CF3 may be located on the fifth insulating layer IL5. A planarization layer OC may be located on the first color filter CF1, the second color filter CF2, and the third color filter CF3. The planarization layer OC, which is for protecting and planarizing an upper surface of the display panel, may include an organic insulating material and may be a single layer or multiple layers. The organic insulating material may include one or more materials selected from the group consisting of polyimide, polyamide, acrylic resin, benzocyclobutene, and phenol resin. The descriptions of the components of FIG. 3 may be applied to other components of FIG. 5, and thus, descriptions of the other components will be omitted below.

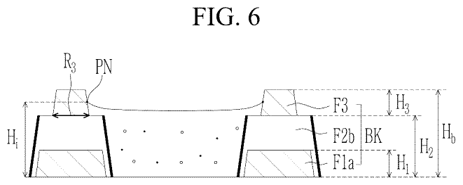

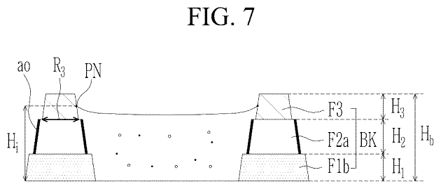

Hereinafter, further details of a bulkhead structure of a display panel according to some embodiments will be described in more detail with reference to FIGS. 6 to 7. FIGS. 6 and 7 are cross-sectional views of a display panel according to some embodiments.

Referring to FIG. 6, the bulkhead BK according to some embodiments includes the first layer F1a, a second layer F2b, and the third layer F3. The first layer F1a may be arranged to overlap the second layer F2b, and the second layer F2b may entirely cover side surfaces of the first layer F1a. Accordingly, a height ratio of the second layer F2b may be increased, and thus, a reflectance of the bulkhead BK may be further increased. A material constituting each layer is the same as that of FIG. 5.

The entire height H_{b} of the bulkhead BK is greater than the maximum height Hᵢ of a color conversion layer. In this case, a difference between the maximum height Hᵢ of the color conversion layer and the entire height H_{b} of the bulkhead BK is 0.5 μm or more.

The height H₁ of the first layer F1a is 0.3 times or less the maximum height Hᵢ of the color conversion layer. Likewise, the height H₃ of the third layer F3 is 0.3 times or less the maximum height Hᵢ of the color conversion layer. The height H₂ of the second layer F2b is 0.6 times or more the maximum height Hᵢ of the color conversion layer.

Also, in order to facilitate the ink process, the maximum width R3 of the lower surface of the cross-section of the third layer F3 may be 6 μm or less. The maximum width R₃ of the third layer F3 may be less than 3 μm as the height H₁ of the first layer F1a and the height H₃ of the third layer F3 decrease, which may exhibit the effect that the less the maximum width R₃ of the third layer F3, the higher the aperture ratio.

Referring to FIG. 7, the bulkhead BK according to some embodiments includes a first layer F1b, the second layer F2a, and the third layer F3. The embodiments of FIG. 7 are the same as the embodiments of FIG. 5 except that the first layer F1b includes a first material having a first reflectance instead of a light blocking material.

The first material of the first layer F1b has the first reflectance, and a second material of the second layer F2a has a second reflectance. In this case, the first reflectance is less than the second reflectance. The first material of the first layer F1b may include MTO (MgTiO₃). In the case of the first material of the first layer F1b is different from the second material of the second layer F2a in the reflectance, and has the reflectance lower than that of the second material of the second layer F2a, the first material of the first layer F1b may be used without being limited thereto.

In this case, the second material of the second layer F2a may be formed of a single material including at least one of a metal or a metal oxide, or may be formed of a material in which particles including the metal and the metal oxide are dispersed in a photosensitive resin composition. The second material may include at least one of aluminum (Al), titanium dioxide (TiO₂), silver (Ag), gold (Au), platinum (Pt), aluminum oxide (Al₂O₃), or zinc oxide (ZnO). The second material of the second layer F2a may be used when the reflectance of the second material of the second layer F2a is higher than that of the first material of the first layer F1b.

In this case, the entire height H_{b} of the bulkhead BK is greater than the maximum height Hᵢ of a color conversion layer. A difference between the maximum height Hᵢ of the color conversion layer and the entire height H_{b} of the bulkhead BK is 0.5 μm or more. The height H₁ of the first layer F1b is 0.3 times or less the maximum height Hᵢ of the color conversion layer. Likewise, the height H₃ of the third layer F3 is 0.3 times or less the maximum height Hᵢ of the color conversion layer. The height H₂ of the second layer F2a is 0.4 times or more the maximum height Hᵢ of the color conversion layer. Also, in order to facilitate the ink process, the maximum width R3 of the lower surface of the cross-section of the third layer F3 may be 6 μm or less. The maximum width R₃ of the third layer F3 may be less than 3 μm as the height H₁ of the first layer F1b and the height H₃ of the third layer F3 decrease, which may exhibit the effect that the less the maximum width R₃ of the third layer F3, the higher the aperture ratio.

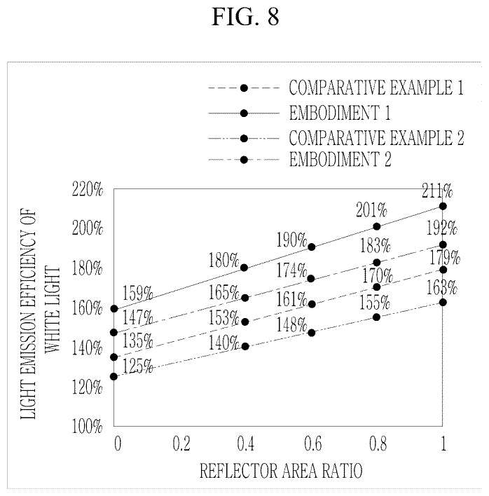

Hereinafter, light emission efficiency of a display device according to embodiments and comparative examples will be described with reference to FIG. 8. FIG. 8 is a graph showing light emission efficiency of white light of the display panel according to embodiments and comparative examples.

The x-axis is a reflector area ratio, and indicates how much a metal and a metal oxide are included in the bulkhead BK. The y-axis indicates the light emission efficiency of white light including all RGB.

In Comparative Example 1, Embodiment 1, Comparative Example 2, and Embodiment 2, it may be seen that as the reflector area ratio increases, that is, as more metal and metal oxide are included in the bulkhead BK, the light emission efficiency of white light increases.

Comparative Example 1 and Embodiment 1 show a panel structure using a single substrate as the embodiments of FIG. 5. Comparative Example 1 shows the display panel including the bulkhead BK in a single structure of an existing organic layer, and Embodiment 1 shows the display panel including the bulkhead BK in a triple structure. Comparative Example 1 shows the light emission efficiency of white light of the display panel having an aperture ratio of 38.8% (or about 38.8%), and Embodiment 1 shows the light emission efficiency of white light of the display panel having an aperture ratio of 66.3% (or about 66.3%). In this case, it may be seen that the light emission efficiency of white light increases by 18% (or about 18%) in Embodiment 1 compared to Comparative Example 1.

Comparative Example 2 and Embodiment 2 show a panel structure using two substrates as the embodiments of FIG. 3. Comparative Example 2 shows the display panel including the bulkhead BK in a single structure of an organic layer, and Embodiment 2 shows the display panel including the bulkhead BK in a triple structure. Comparative Example 2 shows the light emission efficiency of white light of the display panel having an aperture ratio of 38.8% (or about 38.8%), and Embodiment 2 shows the light emission efficiency of white light of the display panel having an aperture ratio of 66.3% (or about 66.3%). In this case, it may be seen that the light emission efficiency of white light increases by 18% (or about 18%) in Embodiment 2 compared to Comparative Example 2.

According to FIG. 8, when the bulkhead BK is formed in the triple structure, the aperture ratio may increase so that the light emission efficiency of white light may be relatively improved, and at least one of metal or metal oxide, which are reflective materials, may be included in the second layers F2a and F2b, and thus, the light emission efficiency of white light may be further improved. Accordingly, in the case of the bulkhead BK of the triple structure of the present embodiments is included, efficiency of the display panel may be maximized or improved.

The display device described above may be applied to a variety of electronic devices. The electronic device according to an embodiment may include the display device described above and may further include modules or devices having other additional functions in addition to the display devices.

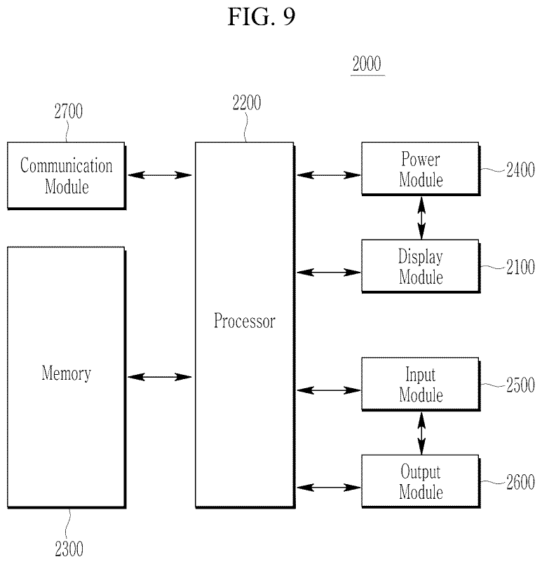

FIG. 9 is a block diagram of the electronic device according to an embodiment. Referring to FIG. 13, the electronic device 2000 may include a display module 2100, a processor 2200, a memory 2300, and a power module 2400. The electronic device 2000 may further include an input module 2500, a non-image output module 2600, and/or a communication module 2700.

The electronic device 2000 may output various information in the form of an image via the display module 2100. When the processor 2200 executes an application stored in the memory 2300, the display module 2100 may provide the user with the visual information provided by the application. The power module 2400 may include a power supply module, such as a power adapter or battery unit, and a power conversion module that converts the power supplied by the power supply module to generate the power required for operation of the electronic device 2000. The input module 2500 may provide input information to the processor 2200 and/or the display module 2100. The non-image output module 2600 may receive non-image information from the processor 2200. Such as sound, haptic, light or other information, and provide it to users. The communication module 2700 is a module responsible for sending and receiving information between the electronic device 2000 and an external device, and may include a receiving part and a transmitting part.

At least one of each of the above-described configurations of the electronic device 2000 may be included within the display device according to the above-described embodiments. Additionally, some of modules that are functionally included within a single module may be included within the display device and others may be provided separately from the display device. For example, the display device may include the display module 2100, and a processor 2200, memory 2300, and power module 2400 may be provided in the form of other devices within the electronic device 2000 other than the display device.

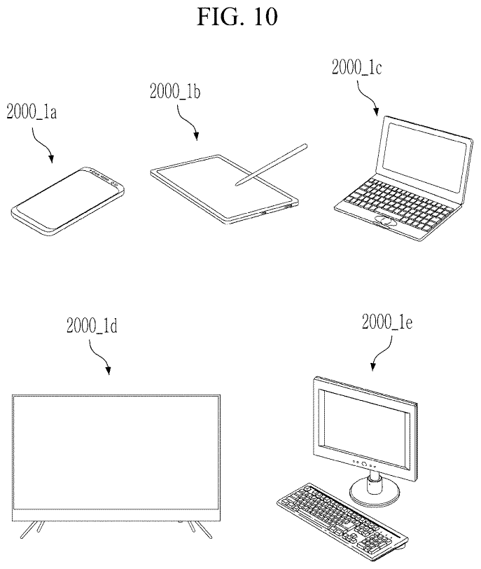

FIGS. 10 to 12 are schematic diagrams of electronic devices according to some embodiments. FIGS. 10 to 12 illustrate examples of various electronic devices with indicating devices according to various embodiments.

FIG. 10 illustrates a smartphone 2000_1a, a tablet PC 2000_1b, a laptop 2000_1c, a TV 2000_1d, and a desk monitor 2000_1e as examples of electronic devices.

The smartphone 2000_1a may include the input module such as a touch sensor and the communication module in addition to the display module 2100. The smartphone 2000_1a may process information received through the communication module or other input module and display the information through the display module of the display device.

The tablet PC 2000_1b, the laptop 2000_1c, the TV 2000_1d, and the desk monitor 2000_1e also may include the display modules and the input modules similar to the smartphone 2000_1a, and in some cases may further include communication modules.

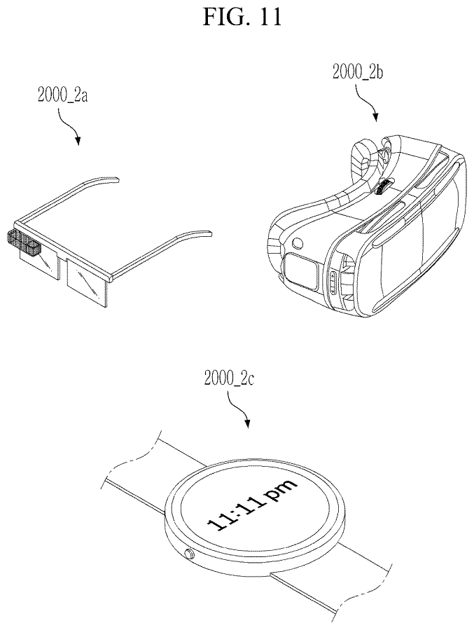

FIG. 11 illustrates an electronic device including the display module applied to a wearable electronic device. The wearable electronic device may include a smart eyewear 2000_2a, a head-mounted display 2000_2b, a smart watch 2000_2c, etc.

The smart glass 2000_2a and the head-mounted display 2000_2b may include the display module that emits a display image and provides it to the user's eyes, thereby providing a virtual reality view or augmented reality view to the user.

The smartwatch 2000_2c may include a biometric sensor as the input device, and may provide biometric information recognized by the biometric sensor to the user through the display module.

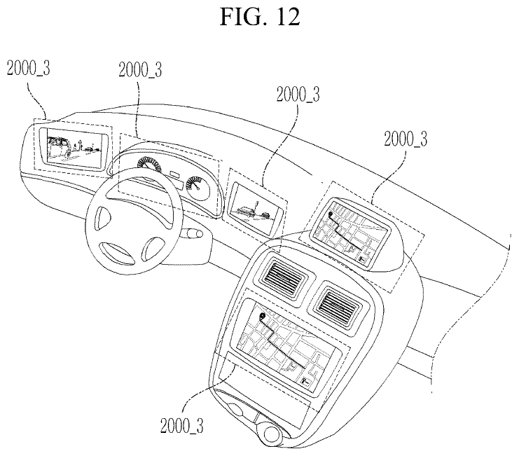

FIG. 12 illustrated an example of the electronic device including the display module applied to a vehicle. For example, the electronic device 2000_3 may be applied to an instrument panel, a center fascia, etc. of the vehicle, or to a center information display (CID) placed on a dashboard of the vehicle, or to a room mirror display that replaces a side mirror.

Although aspects of some embodiments of the present disclosure have been described in detail above, the scope of embodiments according to the present disclosure is not limited thereto, and various modifications and improvements made by those of ordinary skill in the field to which the disclosure pertains also belong to the scope of embodiments according to the present disclosure.

What is claimed is:

1. A display device comprising:
a first substrate;
a transistor on the first substrate;
a light emitting device layer electrically connected to the transistor;
a plurality of color conversion layers above the light emitting device layer; and
a bulkhead between the plurality of color conversion layers,
wherein the bulkhead comprises a first layer, a second layer, and a third layer,
the first layer comprises a light blocking material, and
the second layer comprises at least one of a metal or a metal oxide.

2. The display device of claim 1, wherein:
a height of the second layer is 0.4 times or more a maximum height of a color conversion layer from among the color conversion layers.

3. The display device of claim 1, wherein:
the second layer includes a photosensitive resin composition in which particles including at least one of the metal or the metal oxide are dispersed, and
at least one of the metal or the metal oxide includes at least one of aluminum, titanium dioxide, silver, gold, platinum, aluminum oxide, or zinc oxide.

4. The display device of claim 1, further comprising:
an anti-oxidation layer on both side surfaces of the second layer.

5. The display device of claim 1, wherein:
the third layer includes a liquid repellent material, and
the liquid repellent material includes a copolymer including a perfluoropolyether derivative as a side chain or a branch.

6. The display device of claim 1, further comprising:
a filling layer between a color conversion layer from among the color conversion layers and the bulkhead.

7. The display device of claim 6, further comprising:
a color filter layer on the filling layer.

8. The display device of claim 7, further comprising:
a second substrate on the color filter layer.

9. The display device of claim 1, further comprising:
an insulating layer between a color conversion layer from among the color conversion layers and the bulkhead.

10. The display device of claim 9, further comprising:
a planarization layer on the insulating layer.

11. The display device of claim 1, wherein:
the second layer is stacked on the first layer of the bulkhead, and the third layer is stacked on the second layer.

12. The display device of claim 11, wherein:
the second layer overlaps an upper surface of the first layer and is spaced apart from side surfaces of the first layer.

13. The display device of claim 11, wherein:
when a maximum height of a color conversion layer from among the color conversion layers is Hᵢ, and an entire height of the bulkhead is H_{b},
H_{b} is greater than Hᵢ and H_{b}−Hᵢ≥0.5 μm.

14 The display device of claim 11, wherein:
when a maximum height of a color conversion layer from among the color conversion layers is Hᵢ, and a height of the first layer is H₁, H₁≤0.3 Hᵢ.

15. The display device of claim 11, wherein:
when a maximum height of a color conversion layer from among the color conversion layers is Hᵢ, and a height of the third layer is H₃,
H₃≤0.3 Hᵢ, and a maximum width of the third layer is 6 micrometers (μm) or less on a cross section.

16. The display device of claim 11, wherein:
the first layer overlaps the second layer, and
the second layer covers side surfaces of the first layer.

17. The display device of claim 16, wherein:
when a maximum height of a color conversion layer from among the color conversion layers is Hᵢ, and a height of the second layer is H₂, H₂≥0.6 Hᵢ.

18. A display device comprising:
a first substrate;
a transistor on the first substrate;
a light emitting device layer electrically connected to the transistor;
a plurality of color conversion layers above the light emitting device layer; and
a bulkhead between the plurality of color conversion layers,
wherein the bulkhead comprises a first layer, a second layer, and a third layer,
the first layer includes a first material having a first reflectance,
the second layer includes a second material having a second reflectance, and
the first reflectance is lower than the second reflectance.

19. The display device of claim 18, wherein:
the first material includes MTO(MgTiO₃).

20. The display device of claim 18, wherein:
the second layer includes a photosensitive resin composition in which particles including the second material are dispersed, and
the second material includes at least one of aluminum, titanium dioxide, silver, gold, platinum, aluminum oxide, or zinc oxide.

21. An electronic device, comprising:
a display device comprising
a first substrate;
a transistor on the first substrate;
a light emitting device layer electrically connected to the transistor;
a plurality of color conversion layers above the light emitting device layer; and
a bulkhead between the plurality of color conversion layers,
wherein the bulkhead comprises a first layer, a second layer, and a third layer,
the first layer comprises a light blocking material, and
the second layer comprises at least one of a metal or a metal oxide.
